(19) United States
(12) Patent Application Publication
(10) Pub. No.: US 2006/0054594 A1
(43) Pub. Date: Mar. 16, 2006

(54) Method for the manufacture of a display

(76) Inventors: Herbert Lifka, Eindhoven (NL); Stein Kuiper, Eindhoven (NL)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/537,108

(22) PCT Filed: Oct. 31, 2003
(86) PCT No.: PCT/IB03/04937

§ 371 Date: Jun. 1, 2005

(30) Foreign Application Priority Data
Dec. 3, 2002 (EP) 02080057.9

(51) Int. Cl. C23F 1/00

(52) U.S. Cl. 216/41

(57) ABSTRACT

A method for the manufacture of displays, in particular flexible displays, is disclosed. A substrate (1) provided with small openings (2), rendering the substrate porous and forming trenches in the substrate (1), is used. A removable layer (3) is attached to the substrate (1). An etch and temperature resistent layer (4) is deposited onto the removable layer (3), and a display is processed on said etch and temperature resistent layer (4). The removable layer (3) is removed by etching through the openings (2) in the substrate (1) and the substrate may be re-used.

### FIELD OF THE INVENTION

The present invention relates to a method for the manufacture of a display.

### BACKGROUND OF THE INVENTION

Displays, in particular flexible displays, are a requirement for the future. Flexible displays may be used e.g. for freeshape displays for consumers products, like PDA's and e-books. Round displays, allowing informations to be looked at from any angle while walking around, is of interest for instance when it comes to advertising signs. Another field of application for flexible displays concerns rollup displays, which can be used e.g. for daily papers.

Current methods for manufacturing displays normally involves the use of rigid and expensive substrates. The normal materials used at present are polymers or thin glass. Nevertheless, as stated above, for several applications flexible, light weight displays are desired, which renders it difficult to use rigid substrates during production.

Several display technologies, e.g. active matrix, require higher temperatures to make a good quality display. However, current transparent flexible substrates can not withstand the high temperatures necessary during processing. For example, substrates made of polymers and glass cannot withstand processing temperatures above 250° C. very well.

EP 1 024 523 discloses a method for fabricating thin film semiconductor devices, e.g. solar cells and light emitting diodes. A high quality reusable substrate which is compatible with all high temperature treatments is used. Semiconductor films are grown on a porous layer formed on the surface of the reusable substrate. After being attached to a support, the completed thin film semiconductor devices are lifted off from the substrate by wet etching of the porous layer.

The separation step in order to detach the thin film from the substrate is however a critical step in the method according to EP 1 024 523. Dependent on the size of the substrate, a process is required which allows to perform a lateral etch over several centimeters to remove the porous layer. Furthermore, this etch process has to remove the porous layer in a selective way with respect to the thin film and the semiconductor devices therein, and also with respect to the substrate.

According to EP 1 024 523, the etch mask only prevents one side of the manufactured display to be exposed to the etch solution. In case the display components are sensitive to the etch solution, it is impossible to use the method according to EP 1 024 523, since the etch solution invariably is brought into contact with the display during processing.

Further, according to EP 1 024 523, a lateral etch must be performed in order to remove the display from the substrate. Such lateral etch is difficult to perform, in particular in case the surface of the display to be processed is big, since there is then limited access for chemical solutions to the porous layer. Further, to reduce fabrication costs, also small displays are preferably fabricated on a large substrate to be able to fabricate many displays simultaneously. Due to the limitations of the required lateral etch, the method according to EP 1 024 523 is however not suitable for the production of several small displays on a large substrate.

In addition thereto, the etch resistant support disclosed in EP 1 024 523 is preferably composed of a plastic or a polymer and thus not temperature resistant. Therefore, the support must not be applied until after having processed the display, if the processing requires high temperatures.

### SUMMARY OF THE INVENTION

It is therefore an object of the present invention to provide a cheap, simple and reliable method for the manufacture of displays, specifically flexible displays, allowing high temperature processing of displays and re-use of the substrate by etching of a removable layer, without bringing the etchant into contact with the display.

This and other objects are achieved by using a method for the manufacture of a display comprising
providing a substrate
depositing a removable layer to said substrate covering at least a part of said substrate,
   characterized in
depositing an etch and temperature resistant layer on said removable layer, essentially covering said removable layer,
processing a display on at least part of said etch and temperature resistant layer, and
removing said removable layer by etching with an etchant, said etch and temperature resistent layer preventing the etchant from making contact with said display.

In the research work leading to the present invention, a new approach to fabricating displays employing a re-usable substrate and a removable layer was developed.

The present inventors surprisingly found a way to deposit an etch and temperature resistant layer covering the removable layer, thereby enabling processing the display on the etch and temperature resistant layer and re-use the substrate by etching the removable layer, without bringing said etchant into contact with said display.

The temperature resistance of the etch and temperature resistant layer thus allows high temperature display processing to be performed on a reusable substrate, without necessitating the display components to get into contact with the etchant.

The measure as defined in claim 2 has the advantage that the etching is performed simultaneously over a greater surface, allowing a more rapid and uniform etching of the removable layer, as compared with prior art where lateral etching is performed. It is to be noted that the advantages of having a substrate provided with etch openings is achieved irrespective whether an etch and temperature resistent layer is present or not.

The measures as defined in claim 3-6 have the advantages that silicon/polysilicon is a very robust material, and the process steps and equipment is readily available.

The measure as defined in claim 7 has the advantage that the display can be fabricated into different shapes.

These and other aspects of the invention will be apparent from and elucidated with reference to the embodiments described hereinafter.

### BRIEF DESCRIPTION OF THE DRAWING

FIG. 1 is a schematic build-up of the method according to the invention.

FIG. 2 is a cross-sectional view of the substrate, layers and etch openings according to the invention.

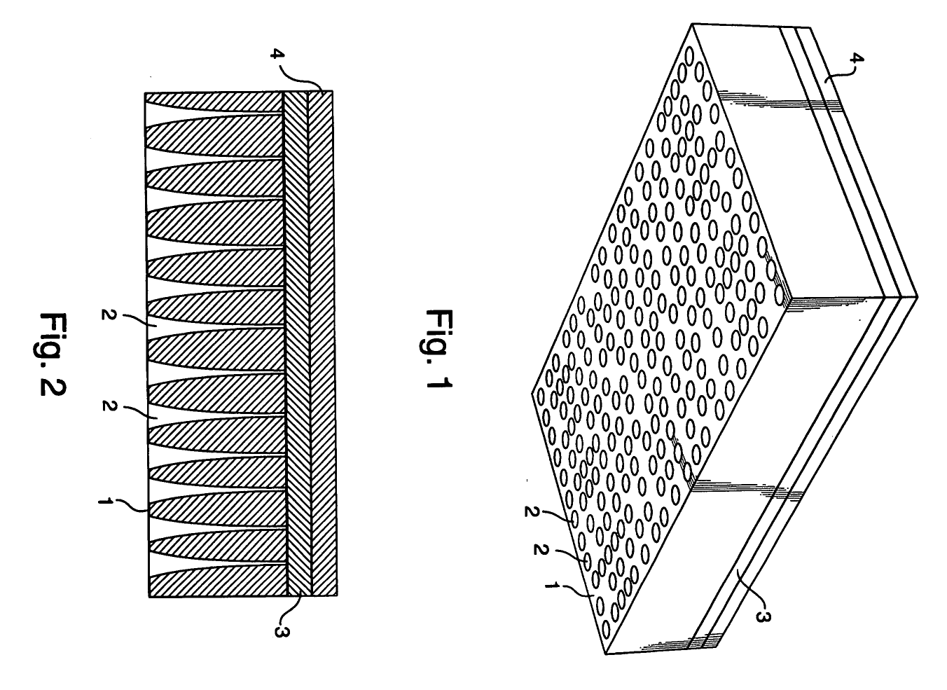

### DESCRIPTION OF PREFERRED EMBODIMENTS

The present invention will now be described in more detail with reference to the accompanying drawing.

The substrate (1) has on the processing side small etch openings (2) which are closed by a removable layer (3) (non conformal deposition). If needed a succeeding planarisation and anneal can be applied (not shown). Essential is the further deposition of an etch and temperature resistant layer (4). The display is processed on this etch and temperature resistent layer (4).

After the complete display processing the display is released from the substrate by wet etching through the etch openings (2) in the substrate (1). The etchant can enter the openings from the backside of the substrate and etch the removable layer on the frontside of the substrate. The etchant is stopped by the etch and temperature resistant layer (4) on which the display was processed. Subsequently the displays are cut loose and if needed proctected. The substrate (1) can be cleaned and used again.

The term “substrate” as used herein refers to a support used for the production of displays. The substrate constitutes the structurally stable material on which the component/s is/are fabricated.

The term “etch openings” as used herein refers to small holes in the substrate, rendering the substrate porous and forming trenches in the substrate through which the etchant is able to pass through.

The term “removable layer” as used herein refers to a non conformal deposition closing the etch openings. The removable layer is dissolvable by the etchant and is sacrificed when detaching the display from the substrate. The removable layer also has to be temperature resistant.

The term “etch and temperature resistant layer” as used herein refers to a strong, temperature resistant layer, an etch mask, which seals the removable layer and is unaffected by the etchant. Further, it is unaffected by high temperatures during processing the display

The term “etching” as used herein refers to the reacting of a material, and the formation of dissolvable products.

The term “etchant” as used herein refers to a solution being able to etch the removable layer, but not the etch and temperature resistant layer, without harming the display.

Substrates and Etch Openings

Porous re-usable substrates for use in the method according to the invention may be constructed by several different methods. Preferably, said substrate comprises a silicon material. Also other substrates, e.g. steel or ceramics, could be used but are less well known.

The most preferred substrate for use in the method according to the invention is made of polysilicon. Polysilicon is available in any dimension, so also real large displays could be made. The etch openings in the substrate are made by a double plasma etch method.

On the silicon material a 1 μm silicon oxide is grown in a furnace (in H₂O/O₂ 880%/12% at 1000° C.). On the front side the (the side of the display to be processed) of this oxide a resist is coated, exposed and developed with a small line pattern with dimensions in one direction smaller then 2 μm. The resist mask is used to etch the oxide in a plasma oxide etcher. The oxide is then used as the main mask to etch the silicon to a depth of about 40 μm. The resist is removed with an oxygen plasma (barrel) and a 50 nm oxidation is performed. With LPCVD a 100 nm SiN deposition is performed. The backside is coated with resist, exposed and developed with a large lines or circle (gives holes) pattern. (Lines were used, but circles should also work. The line where put 90° rotated to the lines on the frontside.) Again the oxide is etched and then the silicon is etched down to the SiN in the grooves. Again the resist is removed, 100 nm silicon oxide is grown and the SiN is etched in H3PO4/H2SO4 at 140C. Then a protecting LPCVD SiN is deposited.

Another cost-effective method for obtaining a substrate for use according to the present invention is anisotropic wet etching in <110> silicon wafers. Using a KOH solution vertical trenches can be etched in <110> silicon. On the front side of the wafer long trenches with a width of the order of 1 μm can be etched. The trench-to-trench distance can also be chosen of the order of 1 μm. A larger distance gives stronger substrates, but longer times for the substrate release etch after completing the display processing. The achievable length-to-width ratio of the trenches depends on the accuracy of the lithography step. The small trenches do not have to be etched entirely through the wafer, as large trenches can be etched from the back side of the wafer to meet the small trenches.

Commercially available silicon microsieves may be also be used in the method according to the invention. These sieves consist of a microporous silicon nitride membrane attached to a macroporous silicon support. They are fabricated using a combination of wet and dry etching techniques.

A further process may also be used to obtain a substrate for use in the method according to the invention, in which holes are etched through a silicon wafer using an HF solution and UV-light.

Preferably, the substrate takes the form of a plane plate. If a special frontplate of the display is required the substrate could have the opposite shape. One could think of small lenses on the display, special outcoupling structures. Also displays with non planar front or back planes could be made, e.g. displays with special outcoupling structures or lenses for e.g. 3D televison.

Further, the substrate may have a height profile which can be passed on to the display to form a structure on the display after detaching. Thus, substrates of any geometrical shape or dimension could be used in the method according to the invention.

The etch openings are preferably formed in such a manner that they are arranged perpendicular to the removable layer after application of the removable layer. However, the arrangement of the openings are not essential for the invention as long as the etchant is capable of passing through the substrate and contacting the removable layer.

In another embodiment of the invention part of the substrate has holes going through the substrate. Preferably no openings are formed at the edges, in order to facilitate the subsequent detachment of the display.

In a preferred embodiment of the invention, there is provided a groove pattern on top of the substrate with less openings going through the complete substrate.

Preferably, there are small openings on the frontside and a few larger openings reach from the backside towards the small openings.

Deposition of Removable Layer

On the perforated substrate a 5 μm PECVD 300° C. SiO₂ deposition at high pressure is performed. This closes the holes up to 2 μm. Other examples of suitable removable layers that could be used are LPCVD of SiO₂. AlO would also be suitable, as well as some metals. E.g. Al should work if deposited with sputtering, or maybe also with PVD.

Plasma Enhanced Chemical Vapor Deposition (PECVD) is a technique in which one or more gaseous reactors are used to form a solid insulating or conducting layer on the surface of a wafer enhanced by the use of a vapor containing electrically charged particles or plasma, at lower temperatures.

The closing of the openings in the perforated substrates has been successfully tested.

Planarisation of the Substrate

Optionally, the substrate can be planarised with e.g. SOG (Spin On Glass) or by Chemical Mechanical Polishing. However the remaining indentations are rather small so the planarisation can optionally be omitted.

For some applications the substrate could also have a depth structure to make a special shape on the display. This can be usefull for e.g. making microlenses on the pixels for better light outcoupling. Also more light outcoupling in the planar direction could be gained with this technique. This would be usefull to compensate for the viewing-angle problem of (active matrix) LCD displays.

The substrate preferably is annealed at the highest temperature required in the display process. In the examples a 30 min 800° C. N₂ anneal was used. The oxide remained stable.

Etch and Temperature Resistant Layer for Display Processing

Essential is the further deposition of a strong, transparent, temperature and etch resistant layer.

On the substrates an etch and temperature resistant layer, a seal layer, 200 nm LPCVD Si₃N₄ at 625° C. was deposited. Other examples of suitable etch and temperature resistant layers are stacks of nitride and siliconoxide/silicon nitride e.g. stacks of Si₃N₄ and SiO₂ or SiON or stacks of Si₃N₄ and SiON or stacks of SiO₂ and SiON or stacks of Si₃N₄,SiO₂ and SiON.

On this layer the further display processing can be performed. Preferably, the etch resistant layer is strong, transparent, and temperature resistent.

Low Pressure Chemical Vapor Deposition (LPCVD) is a technique in which one or more gaseous reactors are used to form a solid insulating or conducting layer on the surface of a wafer under low pressure and high temperature conditions.

Display Processing.

(Process Depend on Required Display and is not Essential to the Invention)

Preferably, the method according to the invention is used to manufacture flexible displays, in particular active matrix PolyLED/OLED and active matrix LCD displays.

For an active matrix Polysilicon PolyLED this would mean; process the transistors with the implantations, structuring steps, laser recrystallisation and interconnects. Afterwards the ITO, PEDOT, PPV, cathodes may be deposited. Then lids with getters are glued or thin film packaging is used with a strengthening layer on top.

Detaching Displays

The processed display is detached from the substrate by etching the removable layer.

Etch through the etching openings in the substrates removes the PECVD oxide in 7:1 NH₄F:HF. This etch will etch the oxide, but not the LPCVD Si₃N₄. The displays will still be attached to the edge of the substrate where preferably no openings are formed. Then the displays are cut/loose from the substrate and, if needed, a protecting layer on front of the display. e.g. transparent plastic is glued or attached otherwise.

Suitable etchants will depend on the materials which have to be etched and the materials which should not be etched. For the SiO—SiN combination also other buffered and non buffered HF solutions can be used.

The present invention thus provides a new and improved method for the manufacture of a display, using a reusable substrate and a removable layer. The method according to the invention allows high temperature processing and etching of the removable layer without contacting the display components with the etchant.

The description of preferred embodiments of the invention should in no way be regarded as limiting the scope of the invention. Of course, alternative ways of practicing the invention, e.g. for non display applications like plastic electronics, Passive Integration and MEMS (Micro-ElectroMechanical Systems) is also within the scope of the invention.

1. A method for the manufacture of a display comprising
providing a substrate
depositing a removable layer to said substrate covering at least a part of said substrate,
characterized in
depositing an etch and temperature resistant layer on said removable layer, essentially covering said removable layer,
processing a display on at least part of said etch and temperature resistant layer, and
removing said removable layer by etching with an etchant, said etch and temperature resistant layer preventing the etchant from making contact with said display.

2. A method according to claim 1, wherein said substrate is provided with etch openings and said etching is performed by leading an etchant through the substrate through said etch openings.

3. A method according to claim 1, wherein said substrate comprises a silicon material.

4. A method according to claim 4, wherein said substrate comprises polysilicon plates.

5. A method according to claim 4, wherein said substrate comprises silicon microsieves.

6. A method according to claim 4, wherein said substrate comprises a silicon wafer.

7. A method according to claim 1, wherein said substrate has a height profile which can be passed on to the display.

8. A method according to claim 1, wherein said etch and temperature resistant layer comprises Si₃N₄.

9. A method according to claim 1, wherein said etch and temperature resistant layer comprises stacks of Si₃N₄ and SiO₂.

10. A method according to claim 1, wherein said etch and temperature resistant layer comprises SiON.

11. A method according to claim 1, wherein said etch and temperature resistant layer comprises stacks of Si₃N₄ and SiON.

12. A method according to claim 1, wherein said etch and temperature resistant layer comprises stacks of stacks of SiO₂ and SiON.

13. A method according to claim 1, wherein said etch and temperature resistant layer comprises stacks of Si₃N₄, SiO₂ and SiON.

14. A method according to claim 1, wherein said removable layer comprises SiO₂.

15. A method according to claim 1, wherein said etchant comprises a HF-solution.

16. A method according to claim 1, wherein said etchant comprises NH₄F:HF.

17. A display obtainable using the method according to claim 1.

18. A method according to claim 1 for non display applications, e.g. plastic electronics, MEMS, and Passive Integration.
